(19) United States
(12) Patent Application Publication
(10) Pub. No.: US 2007/0151759 A1
(43) Pub. Date: Jul. 5, 2007

(54) Adhesive free EMC gasket with built-in chassis retention

(75) Inventors: Mark A. Marnell, Kingston, NY (US); Prabjit Singh, Poughkeepsie, NY (US); Ivan O. Svenson, Hyde Park, NY (US)

Correspondence Address: Lily Neff;IBM Corporation - MS P386, 2455 South Road, Poughkeepsie, NY, 12601, US

(73) Assignee: International Business Machines Corporation, Armonk, NY (US)

(21) Appl. No.: 11/325,666

(22) Filed: Jan. 4, 2006

(51) Int. Cl. H05K 9/00

(52) U.S. Cl. 174/354

(57) ABSTRACT

A method and associated apparatus for providing an electromagnetic seal in electrical enclosure of a device. The apparatus comprising of an electromagnetic gasket formed of a thin conductive material, having a first end and an opposing end. The apparatus also includes a conductive chassis disposed in the electrical enclosure and having a first and second protrusions for securing the end of the gasket to the chassis in a manner to provide facility of compression.

### CROSS-REFERENCE TO RELATED APPLICATIONS

This application contains subject matter which is related to the subject matter of the following co-pending applications, filed on the same day, which is assigned to the same assignee as this application, International Business Machines Corporation of Armonk, N.Y. The following applications and patents listed below is hereby incorporated herein by reference in its entirety: U.S. Pat. No. 6,816,390 and U.S. patent application Ser. No. 11/284,744—filed Nov. 22, 2005 (Docket POU920050160US1 and assigned to the same assignee as this application.

### BACKGROUND OF THE INVENTION

1. Field of the Invention

The present invention relates to an electromagnetic compatibility (EMC) sealing apparatus and related method; and more particularly to a dynamic EMC sealing apparatus and method for an electrical enclosure used in computing system environments.

2. Description of Background

It is an industry goal to continuously increase the number of electronic components inside an electronic device. This goal is driven by several key and important reasons. The first and more obvious one is for the convenience of compactness. Compactness allows for selective fabrication of smaller and lighter devices that are more attractive to the consumer. Some of the reasons for such appeal stem from a desire for easier transportation, shipping, installation and storage of such devices. In other instances, when compactness per se is not a driving factor, providing the same number of devices in only a fraction of available footprint allows the remaining space to be filled with more components which will increase system performance and speed. In addition, compactness also allows many of the circuits to operate at higher frequencies and at higher speeds due to shorter electrical distances in these devices. Unfortunately, despite many of the advantages associated with this industry goal, there are several important challenges that have to be overcome by the designers of these systems.

One area where the challenges and advantages provided by such compact densities is increased is in the computer industry. The reliance of many businesses on computers and computer networks in recent years, demands an ever increasing need to provide fast and accurate systems in the smallest and lightest allowable footprint. In a computing environment, whether comprising of a simple personal computer, or a complex system comprising of a number of computers in processing communication with one another, a plurality of printed circuit boards and cards are provided that house many electronic components and even devices.

A particularly challenging area for the designers of these systems is the issue of resolving electromagnetic interference (EMI). As the number of components are increased, electromagnetic leakage concerns continue to grow. This is because every electronic device, emits some form of electromagnetic radiation. If unresolved, EMI can affect system performance, data integrity and speed. Obviously, in larger system environments, the increased number of components that are stored in close proximity to one another, greatly increases the EMI concerns. This is because while such effects can be tolerated when few devices and components exist, the increasing number of components and devices can seriously impact system integrity and performance. This problem is further exacerbated by the improvement in semiconductor devices which allow them to operate at higher speeds, generally causing emission in higher frequency bands where interference is more likely to occur.

Prior art attempts have been made to minimize the interference problem. Electromagnetic compatibility (EMC) requires that emissions from a given device be reduced by shielding or other similar means. Such shieldings are designed not only to reduce emissions from the device itself, but also to reduce sensitivity of the device to external fields such as fields from other devices. One type of such EMI shieldings are EMI gaskets.

In recent designs, it is necessary to use a metallic type of electromagnetic gaskets to provide better conduction with an electrical enclosure in which the printed circuit boards or cards are engaged. A common problem with such gaskets, however, are that they are easily damaged as a result of deflection of gasket during insertion or removal of printed circuit cards that reside in the computing system environment during mundane activities such as during servicing calls. Once the gasket has been damaged, not only does it no longer provides EMI protection for the device but it may even pose a threat for a potential short.

Related U.S. Pat. No. 6,794,571 by Barringer et al. (hereinafter Barringer patent), owned by the same assignee, International Business Machines Corporation, and coauthored by at least some of the inventors of this application, provided a method and apparatus for providing an electromagnetic conduction seal in a device disposed within an electrical enclosure including a metal EMC gasket.

Related patent solved the prior art problem of minimizing damages to such gaskets. This is especially true with EMC metal gaskets that have a spring design. In such gaskets, often one end of the gasket is only attached to a chassis with the other end left hanging without any retention. This other end is especially vulnerable to being damaged by being for example caught in some other object. The Barringer patent introduced a retention mechanism that provided for a lock strip to be fixed to the device. The gasket in that patent was secured to a device that provided limits of deflection of an intermediate portion to the gasket using an external part.

While the Barringer patent solves many of the prior art problems, it is desirable to introduce a mechanism that can be fabricated at the same time as the chassis itself. In addition, providing a mechanism that does not provide a lock strip can allow the gasket to be used in environments where the installation or later exposure to high temperatures (such as caused by heat dissipation issues) can cause the lock strip to come unhinged. An example would be where glue is used and heat or installation can cause the glue to come undone.

Consequently, it would be desirable to introduce an EMC gasket that can be secured to a device without the use of chemical bonding and adhesives. It would be even more beneficial to fabricate such a gasket during the same fabrication process steps as the device itself.

### SUMMARY OF THE INVENTION

The shortcomings of the prior art are overcome and additional advantages are provided through the method and associated apparatus for providing an electromagnetic seal in electrical enclosure of a device. The apparatus comprising of an electromagnetic gasket formed of a thin conductive material, having a first end and an opposing end. The apparatus also includes a conductive chassis disposed in the electrical enclosure and having a first and second protrusions for securing at the ends of the gasket to the chassis.

Additional features and advantages are realized through the techniques of the present invention. Other embodiments and aspects of the invention are described in detail herein and are considered a part of the claimed invention. For a better understanding of the invention with advantages and features, refer to the description and to the drawings

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a perspective docking cassette as per one embodiment of the present invention;

FIG. 2 is an isometric view of the docking cassette of FIG. 1 with its cover removed;

FIG. 3 is an isometric view of the docking cassette of FIG. 1 and 2 with the printed board card removed;

FIG. 4 is a partial view of the operating mechanism of the docking cassette of FIG. 1, 2 and 3 with the card bracket removed;

FIG. 5 is a top down illustration of the gasket as per one embodiment of the present invention; and

FIG. 6 is a perspective illustration showing better gasket details.

FIG. 7 is a cross sectional illustration of the segmentation of the gasket of FIG. 5; and

FIG. 8 is a cross sectional illustration of the gasket and chassis assembly as per one embodiment of the present invention.

### DESCRIPTION OF THE INVENTION

The embodiments provided in conjunction with the following figures provide for a preferred embodiment where the EMC gasket of present embodiment is disposed in a computing environment. It should be noted that this embodiment is only provided for ease of understanding and the teaching of the present invention can equally apply to other devices and in conjunction with other electrical disclosures.

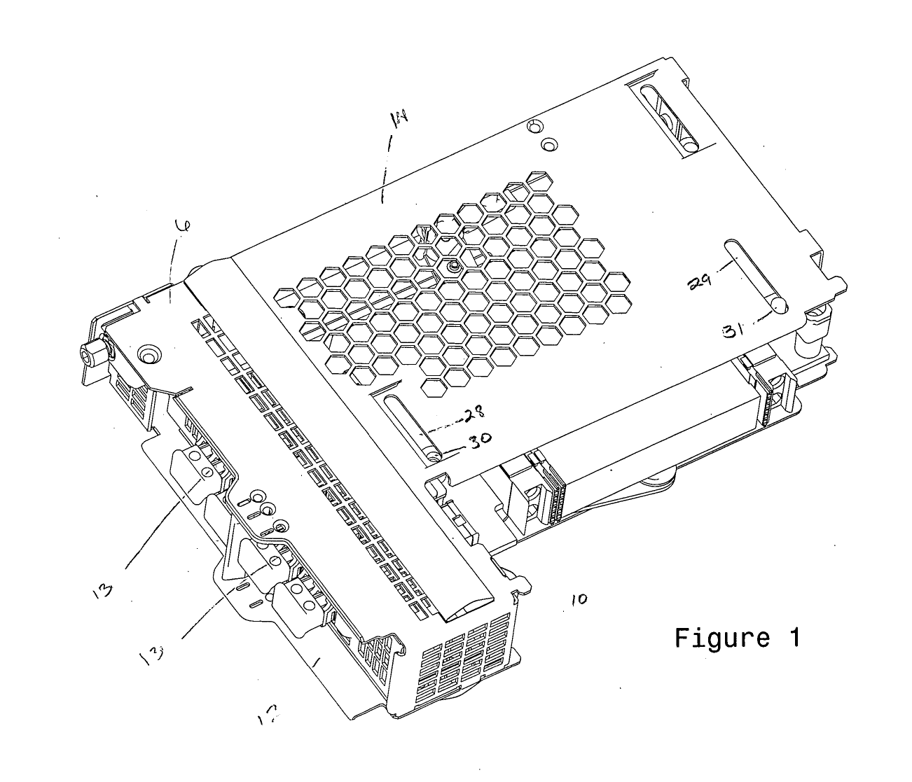

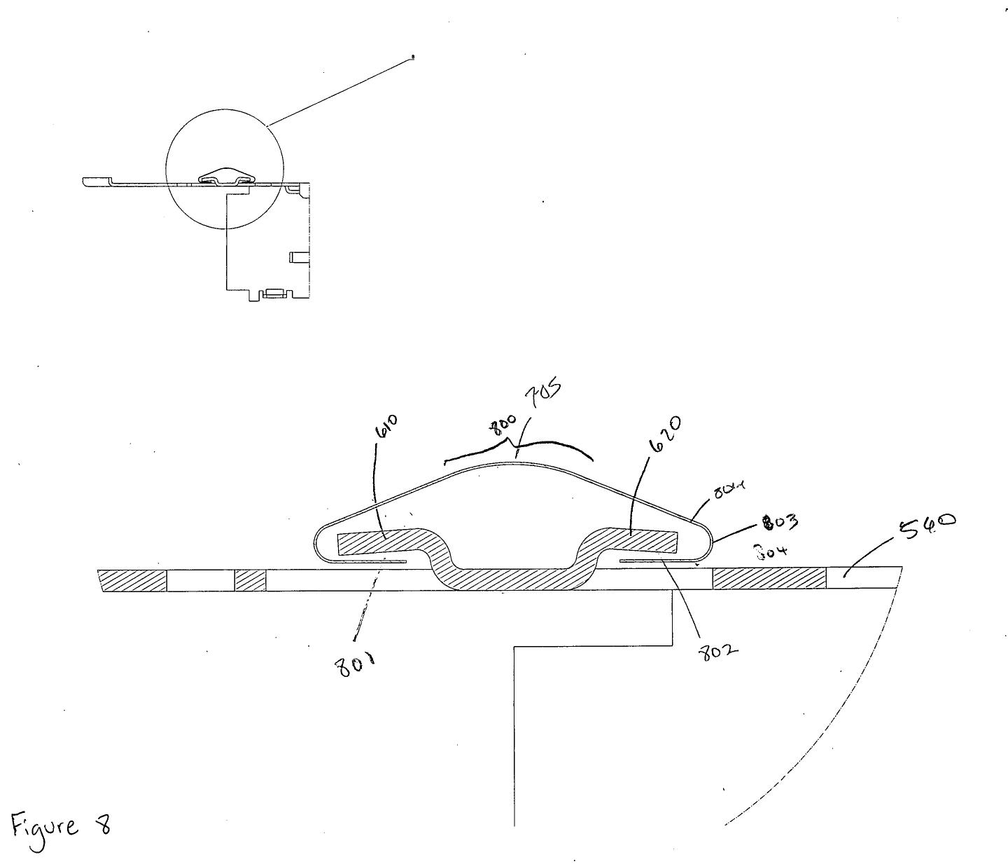

FIG. 8 provides a cross sectional illustration of one embodiment of the present invention. The illustration of FIG. 8, provides for an EMC gasket with a unique retain feature that can be fabricated at the same time and the same material of the gasket and does not require additional adhesives and other such components. Before discussing the unique features comprising the EMC gasket of the present invention, FIGS. 1 through 7 will be discussed so as to provide a general understanding of how the gasket of present invention will be mounted and used in conjunction with other components of a computing environment.

FIG. 1 provides for a perspective view of a docking cassette 10 which will be used in conjunction with the gasket of the present invention. The cassette 10 has a defined cavity 12 containing a carrier 13 for carrying a printed circuit board (PCB) not illustrated in this view. The cassette has a housing 14 which can incorporate an additional cover (not illustrated) that may be selectively mounted on the housing 14 cover to provide better insulation.

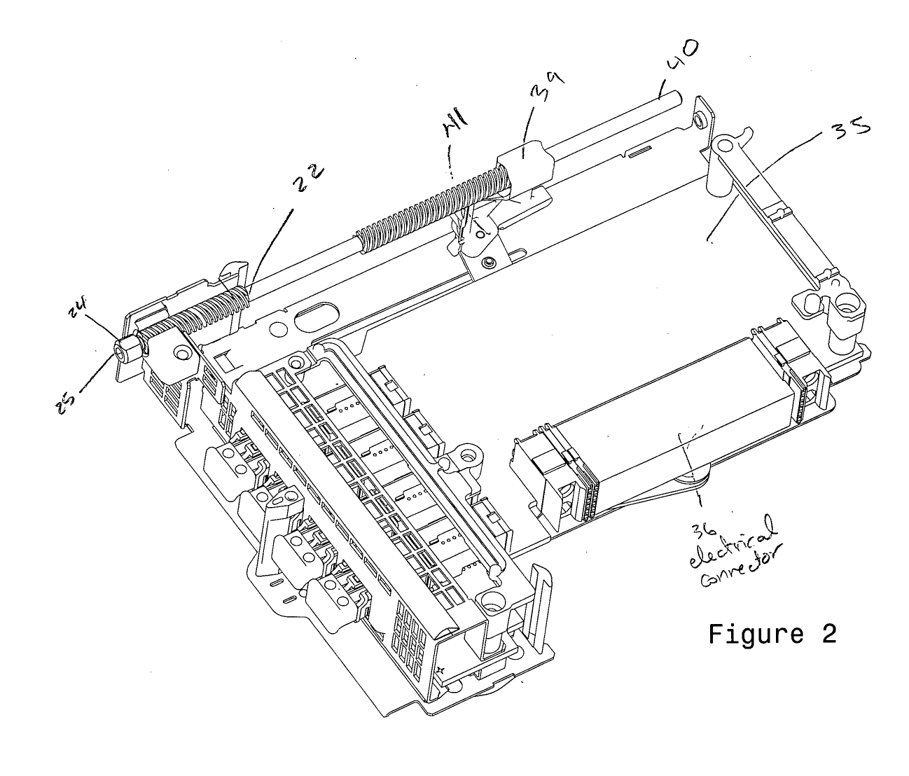

Projections 28 and 29 extend from the carrier 13 within cassette 10 through respective slots 30 and 31 to align the carrier 13 with other features and mechanisms that is provided for the cassette 10 as will be discussed later. FIG. 2 is a perspective view of the cassette 10 of FIG. 1 with the housing 14 removed. As illustrated a rod 22 is shown in this embodiment as being threaded through a threaded bore. The rod has a slightly enlarged head 24 with a socket 25 into which is inserted a tool such as to turn rod 22 to activate the mechanism for seating the PCB as will be discussed.

The removal of the housing 14 in FIG. 2 enables the illustration of PCB 35 to which a plurality of electrical components (not shown) are connected. An electrical connector 36 is also shown. The rod 22 can be used to seat or unseat the PCB 35 and/or the electrical connector 36, through the use of a mechanism 49 which is connected to the PCB 35. A traveling component 39 can be attached to the mechanism 41, which will be discussed in greater detail below to accomplish this.

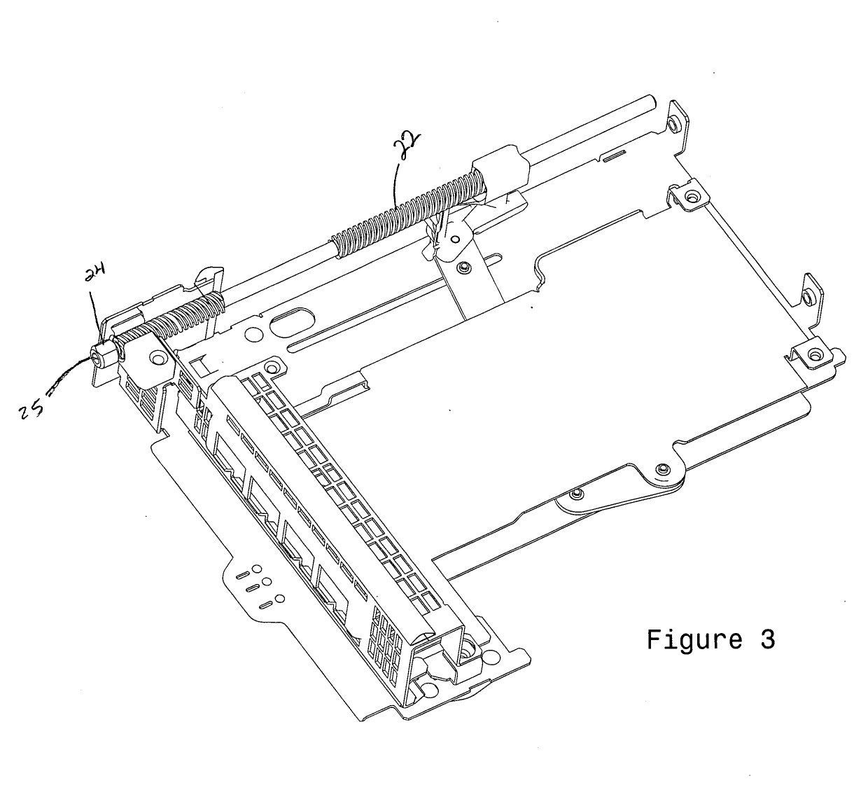

FIG. 3 provides another perspective view of the cassette 10 with the PCB and the electrical connector 36 removed, showing the carrier 13 and the operating mechanism shown to seat and unseat the PCB 35 and/or the electrical connector 36. The mechanism includes a bell crank 42 having a first arm 43 which is pivotally connected to a PCB carrier 13 at 45. It also has a second arm 46 pivotally connected to the traveling component 38 at 48. The bell crank 42 can have a pin (not shown) extending into a horizontal slot 50 in the back of the cassette 10 (not illustrated in this view) to guide the movement of the traveling component 38. In this way the when the traveling component 38 moves, the rotating bell crank 42 also moves in the same direction which causes in turn the downward movement of the carrier 13.

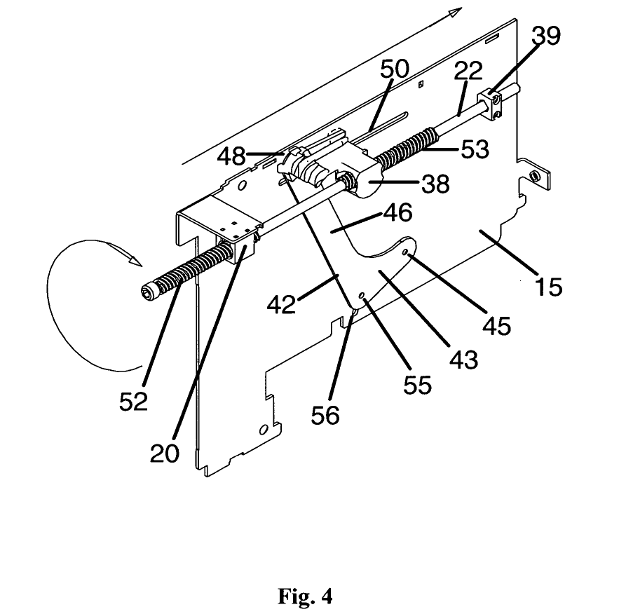

FIG. 4 provides for a partial view of the operating mechanism of the cassette 10 of FIG. 1. The rod 22 has a first enlarged portion 52 which is threaded through for example with a right hand thread. In this example, when the rod is turned clockwise, the rod 22 advances and moves the traveling component 38 toward the right. The rod 22 also has a second enlarged potion 53 which has a left hand thread. Thus, as the rod 22 is turned clockwise, the traveler 38 further moves to the right. It will be understood that the action of both threaded portions 52 and 53 and the traveling component 38 act together in an additive action to rapidly move the traveling component 38 to the right, in this example. The bell crank 42 is pivotally attached to a pin 55 to the back of the cassette illustrated here as 15.

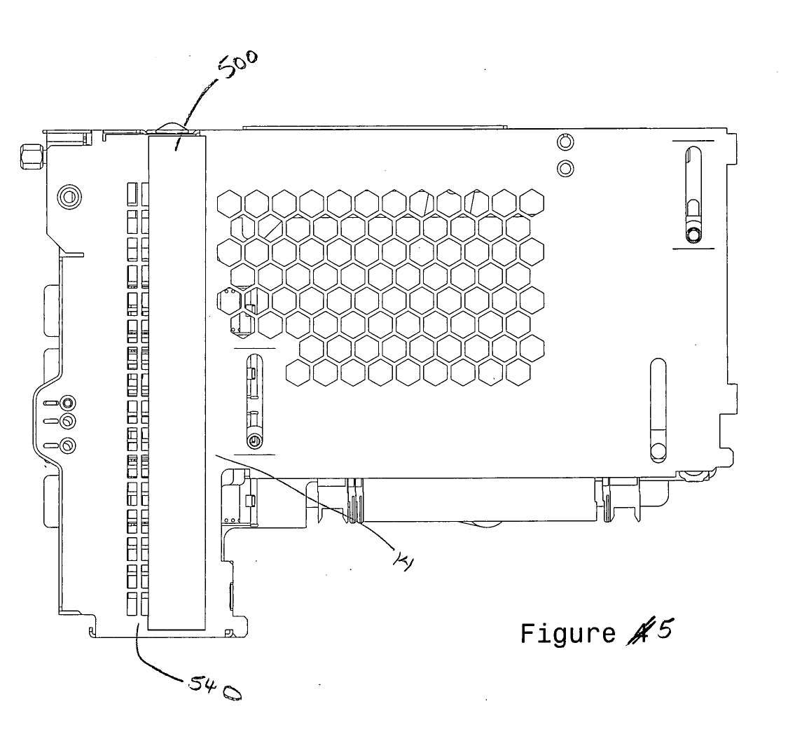

FIG. 5 provides a top down illustration of one embodiment of present invention. The purpose of providing the illustration of FIG. 5 is to focus on the gasket 500 alone. In this regard, other components that may have been already discussed will not be discussed here as not to obscure the discussion of gasket 500. Gasket 500 is placed over a chassis assembly 540 which is part of the initial housing 14 as was illustrated in FIG. 1.

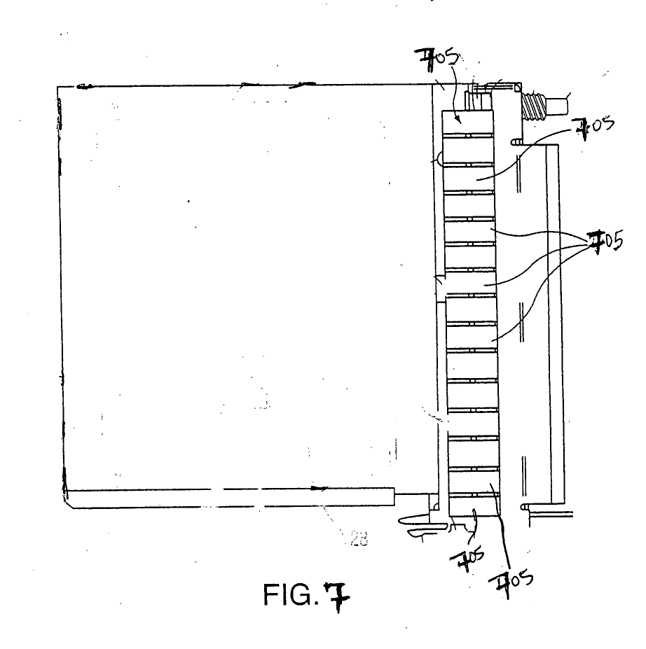

The details of gasket 500 are illustrated in the embodiment of FIG. 5 through 8. In FIG. 5, as per one embodiment of the invention, gasket 500 is provided as a unitary component 500. However, as illustrated in FIG. 7, in a preferred embodiment, the gasket 500 is comprised of a plurality of segments, all of which are referenced as 705 for ease of understanding.

The segmentation of the gasket is related to the amount of EMC control desired. By segmenting the gasket 500, the amount of EMC protection can be increased. In this regard, narrower or wider strips can be used for each segment 705 to selectively reduce or increase the amount of segments 705 that as a whole comprise gasket 500. It should also be noted that while in the illustration of FIG. 7, the segments 705 are illustrated to have equal width, this is not a requirement. Consequently, a combination of widths can also be used such that some segments (705) end up potentially wider than others on the gasket 400. In a preferred embodiment, as illustrated in FIG. 7, independent of width, the shape and topography of each segment, however, is closely similar and/or identical despite the width differences in all conditions.

It should be noted that in a preferred embodiment, the gasket is made out of a single sheet transversally segmented, for example by creating slits selectively preferably such that the opposing ends of the gasket/material are not segmented (and still connected) and the gasket can be put in place as a single unit such as shown in FIG. 5. The slits, once the gasket is secured, form individual loops that independently enhance compression of the gasket as will be discussed later in detail. Such an arrangement is not a requirement, however, and it is possible to have a gasket 500 that is comprised of a plurality of individual segments, that are not attached and that are individually secured to the chasses 540 to collectively form the gasket 500.

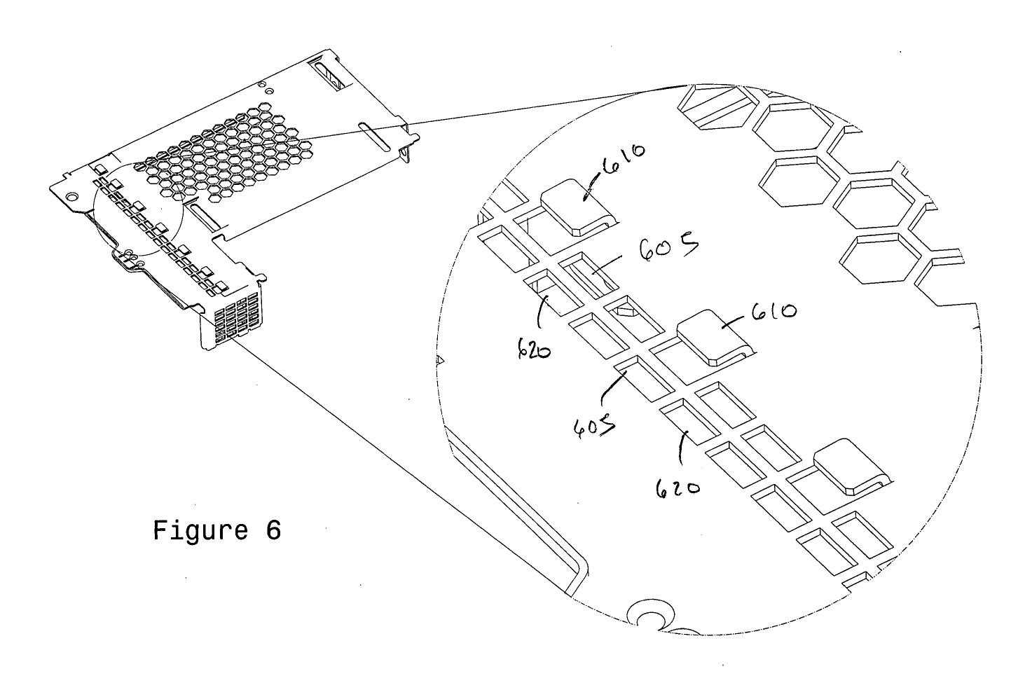

Referring now to FIG. 6, an exploded view of the chassis assembly 540 is provided. A plurality of apertures 605 and protrusions 610 are shown on the chassis assembly 540. In a preferred embodiment, a plurality of second protrusions, marked in areas 620 which are occupied by apertures 605 will be provided. The first and second protrusions, in one embodiment as illustrated can resemble clips in their structure. The first protrusions 610 are preferably in a parallel plane with respect to one another. Similarly, the second protrusions 620 are also preferably on a parallel plane with respect with one another. In addition, the first and second protrusions 610 and 620 can either directly face one another or be in an alternate arrangement where the protrusions 620 lie between the two protrusions 610 as illustrated in FIG. 6. The chassis 600 and the protruding elements 610 and 620 are preferably fabricated of sheet metal during a single fabrication process

Referring now to 7 and FIG. 8, this figure provides a cross sectional depiction of one of the gasket 500. It should be noted, that since a cross sectional view is provided, however, the gasket 500 as a whole is not visible and only the shape of a single strip 705 is visible. Since all such segments 705, however, are nearly identical in this embodiment and the gasket 500 is provided of a plurality of such strips, discussing the topography of a single segment 705 of the gasket 500 also reveals the topography of the gasket 500 as a whole.

Gasket segment 705 is fabricated of a thin sheet of a conductive material. In a preferred embodiment the gasket 705 is fabricated out of a thin sheet of metal, such as copper. The thin sheet of material 705 has opposing ends respectively referenced as 801 and 802 and top and bottom surfaces 803 and 804 respectively.

The thin material of the gasket or gasket segment 705 is attached to the chassis assembly using the protrusions 610 and 620 in the manner illustrated in FIG. 8. As discussed earlier, both protruding elements are preferably fabricated out of the same material as the chassis assembly 540 and are rigid in structure and therefore will hold the gasket 400 or gasket segments 705 firmly in place.

In the illustrated embodiment of the invention, as visibly shown in FIG. 7 and 8, the protrusions have clip like structures that are punched out of chassis sheet metal. This is preferably done in a single processing step at the time of the fabrication of chassis assembly 540.

Referring now to FIG. 8, as illustrated the gasket 500 or alternatively the gasket segments 705 as illustrated in the figure comprise of ends 801 and 802 respectively and top and bottom sides 803 and 804 as illustrated. The ends 801 and 802 are looped around the first and second protrusions 610 and 620 such that the top side 803 of the thin segmented material 705 becomes a bottom portion in areas where the first and second protrusions are disposed over the material. In a preferred embodiment, gasket segment is secured in such a way that provides facility of compression. In the example of the illustrated figure, this means that the gasket 500 is not pulled tightly under the first and second elements 610 and 620 causing the bulbous structure illustrated by referenced element 800.

In the manner described above, each one of the ends 801 and 802 of the thin sheet of material forming the gasket 500 or gasket section 705 is disposed over the chassis assembly 540 through the clips or protrusions 610 and 620. The length of the strip 705 along with the percentage of strip 705 that is used to create the bulbous structure discussed determines the flexibility of the gasket 500 as a whole. In the illustration of FIG. 6, the arrangement that is shown provides a desired spring like quality for the gasket 500 to enhance facility of compression.

In reference to FIG. 8, it should be noted that the protruding elements 610 and 620 serves multiple functions. The more obvious purpose of the protruding elements 610 and 620 is to hold the gasket 500 securely at each end and also allow the gasket 500 to maintain its ability to compress. A less obvious purpose is that since the protruding elements 610 and 620 are preferably made of the same rigid material that forms the chassis assembly 540, it provides support to the thin gasket material such that gasket is not easily torn, damaged or displaced.

The number of the protruding elements provided can also be selectively adjusted to provide more protection if desired. In a functional regard, it is not necessary to have more that a few protruding element for the entire gasket. In such a respect, it would only be necessary to provide a protruding element for every few strips or segments 705. The few protruding elements will hold the gasket 500 securely, but if more secure fastening is desired, the number of elements 610 and 620 as discussed above can be increased.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. An apparatus for providing an electromagnetic seal in electrical enclosure of a device comprising:
an electromagnetic gasket formed of a thin conductive material, having a first end and an opposing end;
a conductive chassis disposed in an electrical enclosure and having at least a first and a second protrusion disposed such ends of said gasket can be looped around under them to securing said gasket to electrical device in a manner to provide facility of compression.

2. The apparatus of claim 1, wherein said gasket is segmented transversely along its length to facilitate compression.

3. The apparatus of claim 2, wherein a plurality of first and second protrusions are provided forming a first and second set of protrusions.

4. The apparatus of claim 3, wherein said electrical enclosure is in a computing environment.

5. The apparatus of claim 4, wherein said first and second set of protrusions directly face one another.

6. The apparatus of claim 5, wherein said first set of protrusions are each in parallel planes with respect to one another.

7. The apparatus of claim 6, wherein said first set of protrusions are each in parallel planes with respect to one another.

8. The apparatus of claim 7, wherein said first and second set of protrusions directly face one another.

9. The apparatus of claim 7, wherein said each of said second protrusions in said second set of protrusions are disposed in between said protrusions in said first set.

10. The apparatus of claim 2, wherein said gasket is not segmented at either end.

11. The apparatus of claim 10, wherein said gasket segmentation form a plurality of slits such that when secured to said chassis, said slits form a plurality of gasket segments with each segment independently facilitating compression.

12. The apparatus of claim 11, wherein said slits are provided equidistantly from one another.

13. The apparatus of claim 12, wherein said segmentation is conducted to provide segments of equal in width.

14. The apparatus of claim 11, wherein said segmentation is performed such that it provides segments of different widths.

15. The apparatus of claim 4, wherein said chassis and said protrusions are fabricated out of sheet metal and/or metal compounds.

16. The apparatus of claim 1, wherein said gasket is fabricated out of metal and/or metal compounds.

17. The apparatus of claim 16, wherein said gasket is fabricated out of copper and/or copper compounds.

18. The apparatus of claim 1, wherein said gasket is used in an electronic device used in a computing environment.

19. The apparatus of claim 3, wherein said first and second sets of protrusions are a plurality of clips.

20. A method for providing an electromagnetic seal in electrical enclosure of a device; comprising:
disposing an electromagnetic gasket having a first end and an opposing end over a metal chassis of an electrical device having a first and a second protrusions;
securing said gasket to said plurality of protrusions on each end using said first and second protrusions such that said gasket provides facility of compression.
